(19) United States
(12) Patent Application Publication
(10) Pub. No.: US 2005/0264334 A1
(43) Pub. Date: Dec. 1, 2005

(54) Semiconductor integrated circuit using latch circuit with noise tolerance

(75) Inventor: Hideyuki Yoneda, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/137,389

(22) Filed: May 26, 2005

(30) Foreign Application Priority Data
May 28, 2004 (JP) 159059/2004

(51) Int. Cl. H03K 3/037

(52) U.S. Cl. 327/205

(57) ABSTRACT

A latch circuit includes a first circuit configured to generate a first output signal from a first input signal and to generate a second output signal from a second input signal; and a first logic circuit connected with the first circuit, and configured to generate a first logic output signal in response to the first output signal and to generate a second logic output signal in response to the second output signal. A first threshold of the first circuit when the first output signal is generated from the first input signal and a second threshold of the first circuit when the second output signal is generated from the second input signal are different from each other.

### BACKGROUND OF THE INVENTION

1. Field of the Invention

The present invention relates to a semiconductor integrated circuit, and more particularly, to a semiconductor memory circuit.

2. Description of the Related Art

Various computers are used under various environments with the advance of computer technology. Noise is possibly superimposed on a signal under some environment. In such an environment, the space is contained in which there are a large quantity of radiation rays and strong electromagnetic waves. The computer contains many semiconductor integrated circuits and the semiconductor integrated circuit is designed in such a manner that the circuit does not malfunctions even when strong electromagnetic waves or radiation rays are irradiated.

FIG. 1 is a circuit diagram showing a conventional latch circuit 100 used under the environment with irradiation of a large quantity of heavy ions. The latch circuit 100 is composed of a first resistance added inverter 101 and a second resistance added inverter 102. As shown in FIG. 1, the first resistance added inverter 101 includes a first resistance element 103 and a first inverter 104. The second resistance added inverter 102 includes a second resistance element 105 and a second inverter 106. Each of the first resistance added inverter 101 and the second resistance added inverter 102 operates similarly for the latch circuit 100 to operate adequately.

FIG. 2 is a schematic diagram showing a state in which heavy ions are irradiated to the latch circuit 100. FIG. 3 is a diagram showing the change of an input voltage in the latch circuit 100 on the irradiation of the heavy ions. The irradiation causes the change of the input voltage, which is applied to the inverters 104 and 106 of the latch circuit 100. Referring to a waveform shown in FIG. 3, a signal with the superimposed noise is applied to the input terminal of each inverter 104 or 106 of the latch circuit 100. However, by configuring the latch circuit of the first resistance added inverter 101 and the second resistance added inverter 102, the voltage change due to the superimposed noise can be suppressed less than the threshold voltages of the inverters 104 and 106 of the latch circuit 100. Thus, it is possible to prevent the circuit from malfunctioning.

However, by adding the resistance, the waveform in a normal operation of the latch circuit 100 is rounded. The latch circuit 100 of the first resistance added inverter 101 and the second resistance added inverter 102 has difficulty to operate in higher speed than a latch circuit (a normal latch circuit) of only the first inverter 104 and the second inverter 106. Therefore, the semiconductor integrated circuit having high tolerance to the radiation rays without decreasing operation speed is demanded.

In conjunction with the above description, an input circuit is disclosed in Japanese Laid Open Patent Application (JP-P2000-295082A). In this conventional example, the input circuit has a first logic circuit, a second logic circuit and a switch circuit. The first logic circuit receives an input signal and output a usual input signal. The second logic circuit is connected with the first logic circuit and functions as a Schmitt circuit with higher and lower thresholds set based on a threshold of the first logic circuit and generates a Schmitt input signal from the input signal. The switch circuit controls connection and disconnection between the first logic circuit and the second logic circuit. Thus, the threshold to the usual input signal is surely set between the hysteresis width of the Schmitt input.

### SUMMARY OF THE INVENTION

In an aspect of the present invention, a latch circuit includes a first circuit configured to generate a first output signal from a first input signal and to generate a second output signal from a second input signal; and a first logic circuit connected with the first circuit, and configured to generate a first logic output signal in response to the first output signal and to generate a second logic output signal in response to the second output signal. A first threshold of the first circuit when the first output signal is generated from the first input signal and a second threshold of the first circuit when the second output signal is generated from the second input signal are different from each other.

Here, the latch circuit may further include a second circuit connected with the first logic circuit and configured to generate a third output signal from the first logic output signal and to generate a fourth output signal from the second logic output signal; and a second logic circuit connected with the second circuit, and configured to output a third logic output signal to the first circuit as the first input signal in response to the third output signal, and to output a fourth logic output signal to the first circuit as the second input signal in response to the fourth output signal. A third threshold of the second circuit when the third output signal is generated from the first logic output signal and a fourth threshold of the second circuit when the fourth output signal is generated from the second logic output signal may be different from each other.

Also, the latch circuit may further include a second logic circuit connected with the first logic circuit, and configured to output a third logic output signal to the first circuit as the first input signal in response to the first logic output signal, and to output a fourth logic output signal to the first circuit as the second input signal in response to the second logic output signal.

Also, at least one of the first circuit and the second circuit may include a buffer circuit; a first resistance component connected with an input of the buffer circuit in series; and a second resistance component connected in parallel to the buffer circuit. In this case, the buffer circuit may include a first inverter; and a second inverter connected with the first inverter in series, and at least one of the first inverter and the second inverter may be an NMOS inverter. Also, at least one of the first inverter and the second inverter may include a PMOS inverter. Also, at least one of the first resistance component and the second resistance component may include a silicon film resistance. Also, at least one of the first resistance component and the second resistance component may include a MOS transistor.

Also, each of the first logic circuit and the second logic circuit may include an inverter. Also, each of the first logic circuit and the second logic circuit may include a NOR circuit. Also, each of the first logic circuit and the second logic circuit may include a NAND circuit.

In another aspect of the present invention, a flip-flop circuit includes a first circuit; and a second circuit connected with the first circuit. The first latch circuit generates a first output signal based on a first threshold in response to a first input signal, and generates a second output signal based on a second threshold value different from the first threshold in response to a second input signal. The second circuit generates a third output signal from the first output signal to output to the first circuit as the first input signal, and generates a fourth output signal from the second output signal to output to the first circuit as the second input signal.

Here, the first circuit may include a hysteresis circuit and a first specific circuit connected to the hysteresis circuit and the second circuit. The hysteresis circuit may generate a first inversion signal based on the first threshold in response to the first input signal, and may generate a second inversion signal based on the second threshold value in response to the second input signal. The first specific circuit may generate the first output signal from the first inversion signal and may generate the second output signal from the second inversion signal. In this case, the first input signal may be a signal transiting from a low level to a high level, and the second input signal may be a signal transiting from the high level to the low level. The first threshold is preferably higher than the second threshold.

In another aspect of the present invention, a semiconductor memory circuit includes a plurality of memory cell circuits arranged in a matrix. Each of the plurality of memory cell circuits includes a first circuit; and a second circuit connected with the first circuit. The first latch circuit generates a first output signal based on a first threshold in response to a first input signal, and generates a second output signal based on a second threshold value different from the first threshold in response to a second input signal. The second circuit generates a third output signal from the first output signal to output to the first circuit as the first input signal, and generates a fourth output signal from the second output signal to output to the first circuit as the second input signal.

In this case, the first circuit may include a hysteresis circuit and a first specific circuit connected to the hysteresis circuit and the second circuit. The hysteresis circuit may generate a first inversion signal based on the first threshold in response to the first input signal, and may generate a second inversion signal based on the second threshold value in response to the second input signal. The first specific circuit may generate the first output signal from the first inversion signal and may generate the second output signal from the second inversion signal.

Also, the first input signal may be a signal transiting from a low level to a high level, and the second input signal may be a signal transiting from the high level to the low level. The first threshold is preferably higher than the second threshold.

Also, the semiconductor memory circuit may further include a bit line connected with each of columns of the plurality of memory cell circuits; and a word line connected with each of rows of the plurality of memory cell circuits.

### BRIEF DESCRIPTION OF THE DRAWINGS

FIG. 1 is a circuit diagram showing a conventional circuit used in the environment with irradiation of a large quantity of the radiation rays;

FIG. 2 is a conceptual diagram showing a latch circuit to which the radiation rays are irradiated;

FIG. 3 is a diagram showing an input voltage change in the latch circuit on the irradiation of heavy ions;

FIG. 4 is a circuit diagram showing a circuit configuration of a semiconductor integrated circuit according to a first embodiment of the present invention;

FIG. 5 is a diagram showing a circuit diagram of each of a first hysteresis function added circuit 1 and a second hysteresis function added circuit 2 in a hysteresis function added latch circuit 10;

FIG. 6 is a diagram showing a first logic circuit 11 carrying out a predetermined logical calculation in response to an inputted signal voltage;

FIG. 7 is a diagram showing a hysteresis characteristic of the first hysteresis circuit 11;

FIG. 8 is a specific example of a flip-flop circuit of a plurality of hysteresis function added latch circuits;

FIG. 9 is a conceptual diagram showing that a radiation ray is irradiated to the hysteresis function added latch circuit;

FIG. 10 is a diagram showing an input voltage change on the irradiation of the heavy ions in the hysteresis function added latch circuit shown in FIG. 9;

FIG. 11 is a conceptual diagram showing that the heavy ions are irradiated to a conventional latch circuit 200;

FIG. 12 is a diagram showing an input voltage change due to the irradiation of the heavy ions in the conventional latch circuit 200 shown in FIG. 11; and

FIG. 13 is a diagram showing a configuration of the semiconductor device according to the second embodiment of the present invention.

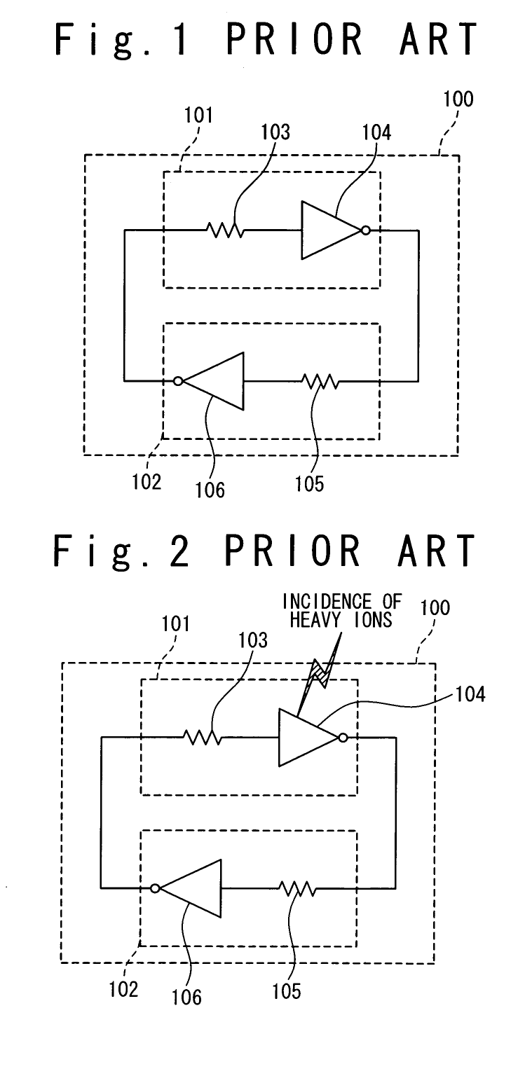

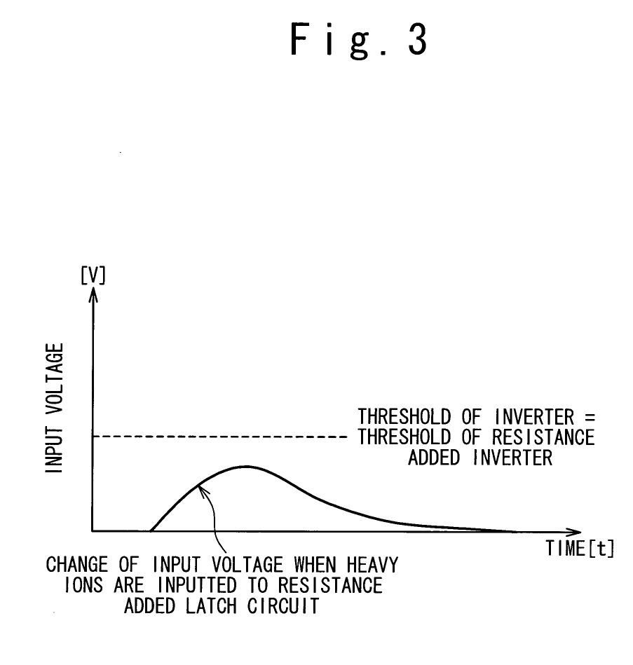

### DESCRIPTION OF THE PREFERRED EMBODIMENTS

Hereinafter, a semiconductor integrated circuit of the present invention will be described in detail with reference to the attached drawings.

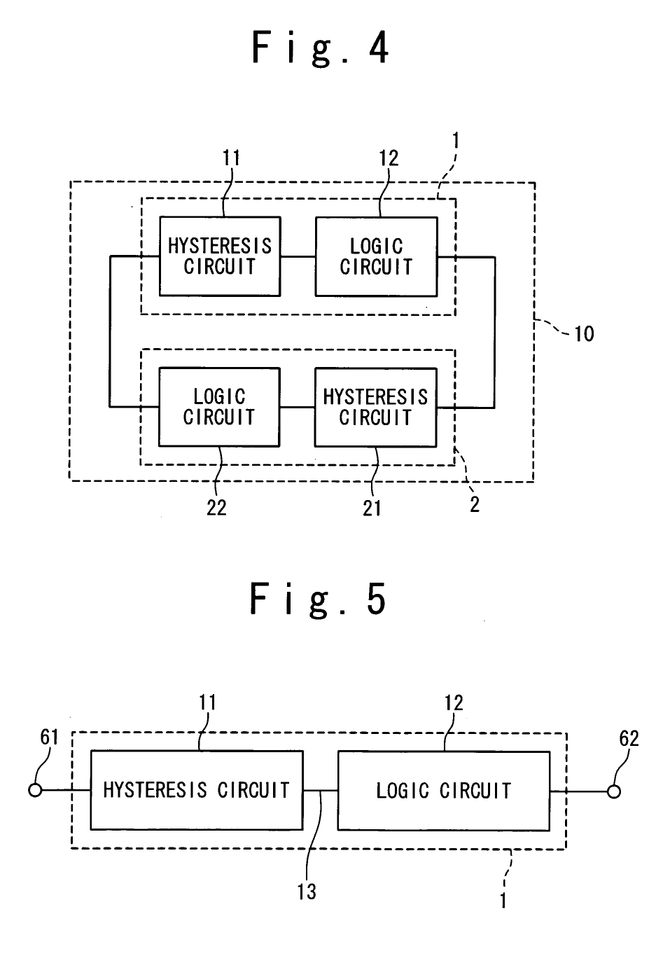

FIG. 4 is a circuit diagram showing a circuit configuration of the semiconductor integrated circuit according to the first embodiment of the present invention. Referring to FIG. 4, a hysteresis function added latch circuit 10 as a memory cell of the semiconductor memory circuit is configured of a first hysteresis function added circuit 1 and a second hysteresis function added circuit 2 in the first embodiment. The first hysteresis function added circuit 1 and the second hysteresis function added circuit 2 are connected to form a loop. An input terminal of the first hysteresis function added circuit 1 is connected to an output terminal of the second hysteresis function added circuit 2, and an input terminal of the second hysteresis function added circuit 2 is connected to an output terminal of the first hysteresis function added circuit 1. The first hysteresis function added circuit 1 includes a first hysteresis circuit 11 and a first logic circuit 12. The second hysteresis function added circuit 2 includes a second hysteresis circuit 21 and a second logic circuit 22, as well as the first hysteresis function added circuit 1.

FIG. 5 is a circuit diagram showing the circuit configuration of the first hysteresis function added circuit 1. The second hysteresis function added circuit 2 has a same circuit configuration as the first hysteresis function added circuit 1. Therefore, only the first hysteresis function added circuit 1 will be described below. Referring to FIG. 5, the first hysteresis function added circuit 1 is configured of the first hysteresis circuit 11 and the first logic circuit 12 as mentioned above. The first hysteresis circuit 11 and the first logic circuit 12 are connected through a node 13. The first hysteresis circuit 11 has a threshold voltage when the input signal transits from a low level to a high level (hereafter, to be referred to as a first threshold voltage) and a threshold voltage when the input signal transits from the high level into the low level (to be referred to as a second threshold voltage). The first and second threshold voltages are different from each other. The first logic circuit 12 in the first embodiment has one output corresponding to one input. However, the logic circuit used in the present invention is not limited to this. The first logic circuit 12 carries out a predetermined logical calculation in response to an inputted signal. In this way, in the first hysteresis function added circuit 1 shown in FIG. 5, an input signal is supplied to the first hysteresis circuit 11 through a node 61. A signal outputted from the first hysteresis circuit 11 in response to the input signal is supplied to the first logic circuit 12 through the node 13. The first logic circuit 12 carries out the predetermined logical calculation in response to the signal, and outputs a voltage signal corresponding to the calculation result to the node 62.

It should be noted that the first hysteresis function added circuit 1 and the second hysteresis function added circuit 2 have the same configuration and the first hysteresis circuit 11 and the second hysteresis circuit 21 have the same circuit configuration. However, the first and second hysteresis function added circuits 11 and 21 may have the different configurations.

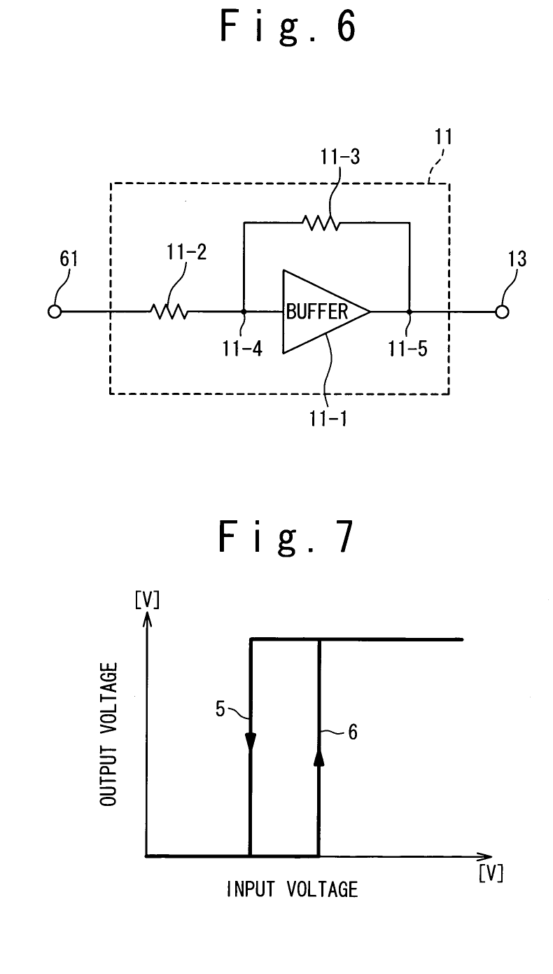

FIG. 6 shows a specific circuit configuration of the first hysteresis circuit 11 of the first hysteresis function added circuit 1. Referring to FIG. 6, the first hysteresis circuit 11 includes a buffer 11-1, a resistance element 11-2 and a resistance element 11-3. The buffer 11-1 is a logic circuit that outputs the same logic signal as an input logic signal. In the first embodiment, the buffer 11-1 is composed of two CMOS inverters connected in series. However, the buffer 11-1 of the present invention is not limited to this. For example, the buffer 11-1 may be composed of two NMOS inverters connected in series, or may be composed of two PMOS inverters connected in series. In addition, the buffer 11-1 may be configured by connecting the NMOS inverter and the PMOS inverter. The resistance elements 11-2 and 11-3 are resistors having predetermined resistance values. The resistance elements 11-2 and 11-3 in the first embodiment are not limited to this. A non-crystalline (amorphous) silicon wiring or polysilicon wiring may be used for the resistance elements 11-2 and 11-3. In addition, an on-resistance of the MOS transistor may be used for the resistances.

Referring to FIG. 6, the buffer 11-1 is connected to the resistance element 11-2 in series. The input signal is supplied from the node 61 to the buffer 11-1 through the resistance element 11-2. Moreover, the buffer 11-1 is connected to the resistance element 11-3 in parallel. The signal outputted from the resistance element 11-2 is supplied to the node 13 through a node 11-4 and the resistance element 11-3 and through the buffer 11-1.

FIG. 7 shows a hysteresis characteristic of the above-mentioned first hysteresis circuit 11. A first waveform 5 shown in FIG. 7 is obtained when the signal transits from the high level to the low level. A second waveform 6 shown in FIG. 7 is obtained when the signal transits from the low level to the high level. As shown in FIG. 7, the first hysteresis circuit 11 generates an output signal by using different threshold voltages depending on whether the signal transits from the high level to the low level, or from the low level to the high level. Then, the first hysteresis circuit 11 outputs the generated signal to the first logic circuit 12.

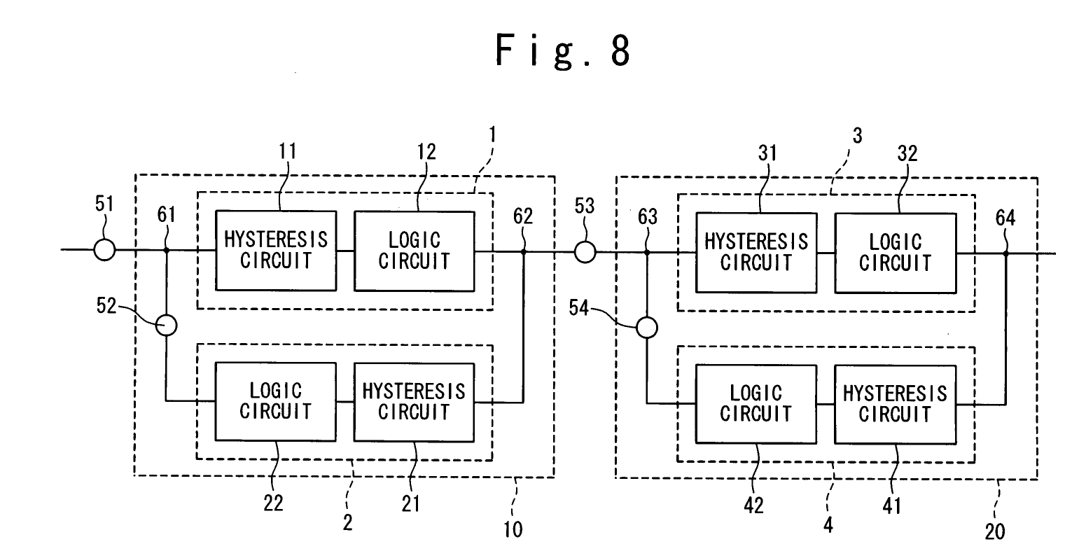

FIG. 8 is a specific example of a flip-flop circuit of a plurality of hysteresis function added latch circuits 10. Referring to FIG. 8, the flip-flop circuit is configured of the hysteresis function added latch circuit 10, a second hysteresis function added latch circuit 20 connected to the hysteresis function added latch circuit 10, and a plurality of transmission gates 51 to 54. Each of the hysteresis function added latch circuit 10 and the second hysteresis function added latch circuit 20 functions a memory cell circuit. The second hysteresis function added latch circuit 20 has the same configuration as the hysteresis function added latch circuit 10. That is, the second hysteresis function added latch circuit 20 is configured of a third hysteresis function added circuit 3 and a fourth hysteresis function added circuit 4. The third hysteresis function added circuit 3 includes a third hysteresis function added circuit 31 and a third logic circuit 32. The fourth hysteresis function added circuit 4 includes a fourth hysteresis function added circuit 41 and a fourth logic circuit 42.

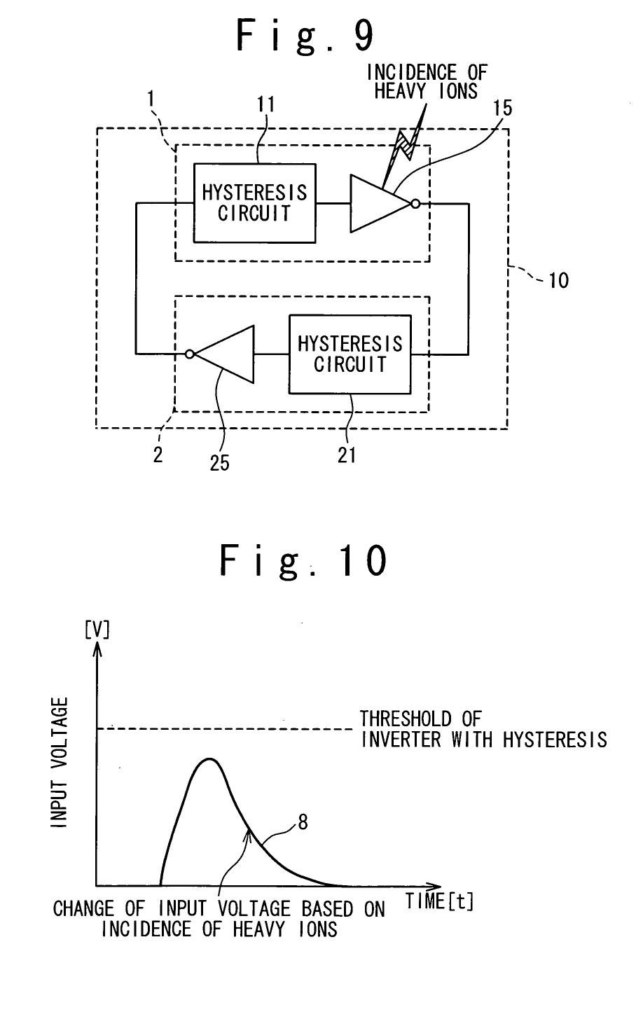

FIG. 9 is a conceptual diagram showing that heavy ions are irradiated to the hysteresis function added latch circuit 10. Referring to FIG. 9, the heavy ions are irradiated to the hysteresis function added latch circuit 10 as an example of the radiation ray. To facilitate the understanding of the present invention, it is supposed that the first logic circuit 12 and the second logic circuit 22 are NOT circuits (inverter). It should be noted that the logic circuit of the hysteresis function added latch circuit of the present invention is not limited to this example. A NAND circuit or a NOR circuit may be applied to the hysteresis function added latch circuit as well as the NOT circuit. A first inverter 15 and a second inverter 25 in FIG. 9 invert input signals and output the inverted signals. In the following description, each of the first inverter 15 and the second inverter 25 is a CMOS inverter as an example. However, the first inverter 15 and the second inverter 25 are not limited to the CMOS inverter in the present invention.

As shown in FIG. 9, the first hysteresis function added circuit 1 is configured of the first inverter 15 whose input terminal is connected to the first hysteresis circuit 11. Similarly, the second hysteresis function added circuit 2 is configured of the second inverter 25 whose input terminal is connected to the second hysteresis circuit 21. As a result, the threshold voltage when the input signal transits from the low level to the high level in the first hysteresis function added circuit 1 is set to be higher than the threshold voltage of the inverter. Moreover, the threshold voltage when the input signal transits from the high level to the low level in the first hysteresis function added circuit 1 is set to be lower than the threshold voltage of the inverter. As a result, the amplitude of the signal voltage necessary to change the output of the first hysteresis function added circuit 1 becomes larger than that before the first hysteresis circuit 11 is added. Thus, a tolerance to the superimposed noise voltage improves.

FIG. 10 shows an input voltage change on the irradiation of the heavy ions in the hysteresis function added latch circuit 10 shown in FIG. 9. Referring to FIG. 10, when the heavy ions are irradiated to the first hysteresis function added circuit 1, the signal voltage changes as shown by a waveform 8 in FIG. 10. When the heavy ions are irradiated to the first inverter 15 in FIG. 10, the output voltage of the first inverter 15 changes regardless of the logical operation of the first inverter 15. Here, the threshold voltage of the hysteresis function added latch circuit 10 is higher than the threshold voltage of the latch circuit of conventional inverters. Therefore, even when the input voltage changes as shown by the waveform 8 due to the irradiation of the heavy particle, the voltage does not reach the threshold voltage of the second hysteresis function added circuit 2. Thus, the output of the first hysteresis function added circuit 2 does not change. The same matter is true to the second hysteresis function added circuit 2. By configuring the hysteresis function added latch circuit 10 of the first hysteresis function added circuit 1 and the second hysteresis function added circuit 2, it is possible to prevent the value latched by the hysteresis function added latch circuit 10 from inverting, even when the heavy ions are irradiated and the noise voltage is superimposed on the signal voltage.

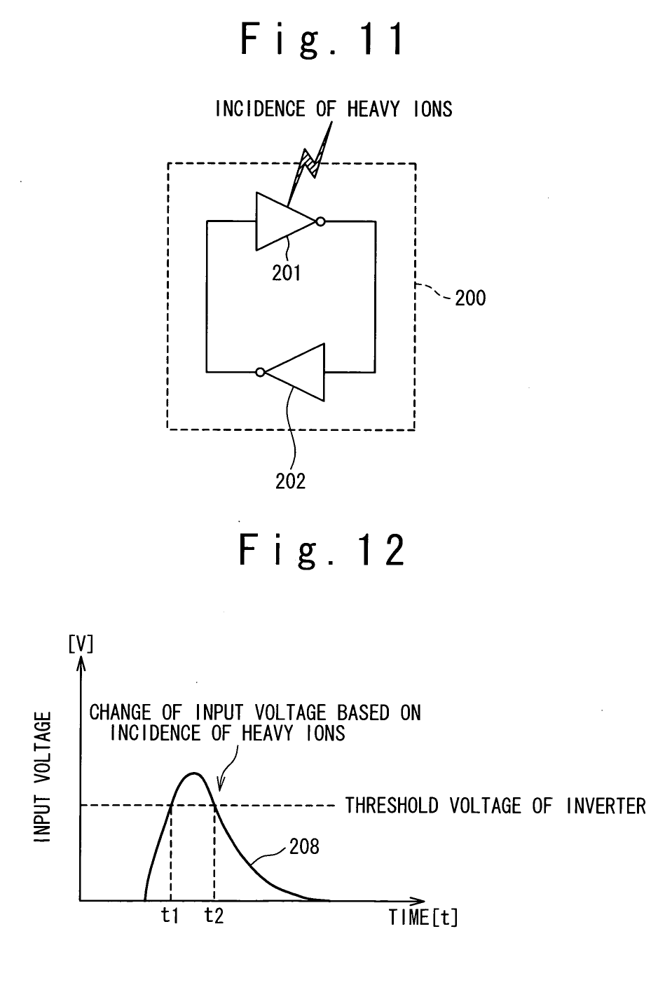

To clarify the effect of the hysteresis function added latch circuit 10 shown in FIG. 10, as operation of the conventional latch circuit when the heavy ions are irradiated will be described simply. FIG. 11 is a conceptual diagram showing that the heavy ions are irradiated to a conventional latch circuit 200. Referring to FIG. 11, the conventional latch circuit 200 is configured of a first inverter 201 and a second inverter 202. FIG. 12 shows an input voltage change due to the irradiation of the heavy ions in the conventional latch circuit 200 shown in FIG. 11. Referring to FIG. 12, the output voltage of the inverter 201 changes as shown by a waveform 208 in FIG. 12 when the heavy particles are irradiated to the first inverter 201 that outputs a low level signal. As shown in FIG. 12, the output voltage of the first inverter 201 exceeds the threshold voltage of the second inverter 202 at a time t1. At this time, the second inverter 202 inverts the output signal in response to the output voltage of the first inverter 201 and supplies the inverted signal to the first inverter 201. As a result, the signal supplied to the input terminal of the first inverter 201 is inverted from the high level to the low level. Therefore, the output of the first inverter 201 is also inverted to the low level from the high level before the irradiation of the heavy ions. That is, the latched data by the inverter 201 is changed from the low level to the high level. In other word, the value latched by the latch circuit is inverted.

As mentioned above, unlike the conventional latch circuit 200, by configuring the hysteresis function added latch circuit 10 of the first hysteresis function added circuit 1 and the second hysteresis function added circuit 2, it is possible to prevent the latched data from inverting even when the radiation ray is irradiated to the hysteresis function added latch circuit 10. In addition, the rounding of the waveform is not generated in the normal operation because any resistance is not added. Therefore, the tolerance to the radiation ray can be improved while suppressing the reduction of the operation speed in the latch circuit.

### Second Embodiment

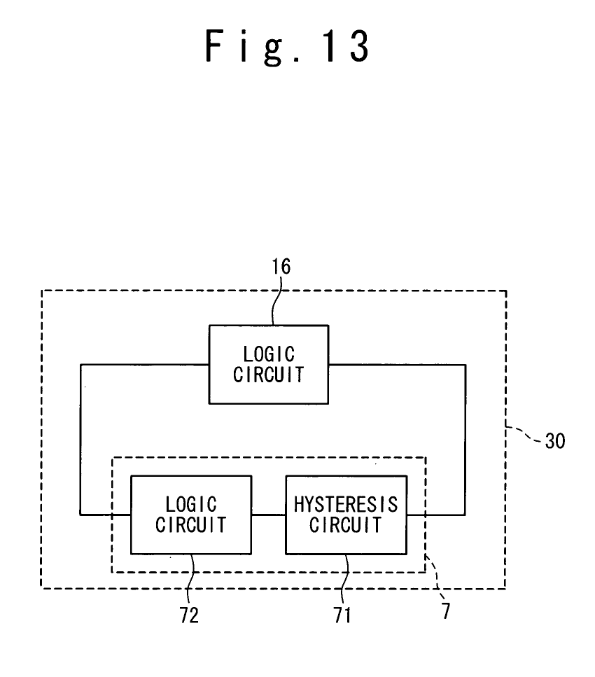

FIG. 13 shows a configuration of the semiconductor device according to the second embodiment of the present invention. Referring to FIG. 13, a third hysteresis function added latch circuit 30 in the second embodiment is configured of a logic circuit 16 and a hysteresis function added circuit 7. The hysteresis function added circuit 7 includes a hysteresis function added circuit 71 and a logic circuit 72. Here, the logic circuit 16 of the third hysteresis function added latch circuit 30 is supposed to be such a circuit that the radiation ray is not irradiated, or that the noise voltage superimposed in response to the radiation does not exceed a threshold voltage. In other word, the hysteresis function added circuit 7 is configured by providing the hysteresis function added circuit 71 for the logic circuit 72 that the latched value is inverted when the radiation ray is irradiated. Such a hysteresis function added circuit 7 and the logic circuit 16 configure the third hysteresis function added latch circuit 30.

As mentioned above, the third hysteresis function added latch circuit 30 is configured of the logic circuit 16 without the hysteresis function added circuit, and the hysteresis function added circuit 7 in which the hysteresis circuit 71 is added to the logic circuit 72. Therefore, the chip area of the third hysteresis function added latch circuit 30 on the semiconductor integrated circuit becomes small, compared with the hysteresis function added latch circuit 10. Thus, when the tolerance to the radiation ray is required in the semiconductor integrated circuit, the semiconductor integrated circuit having the third hysteresis function added latch circuit 30 achieves the reduction of the chip area. In the semiconductor integrated circuit, it is important to reduce the chip area. The semiconductor integrated circuit requires the tolerance to the radiation ray in addition to the reduction of the chip area. Here, the third hysteresis addition latch circuit 30 can be applied to the semiconductor integrated circuit in which the tolerance to the radiation ray may be allowed to be reduced some degree, or applied to a position to which the strong tolerance to the radiation ray is not required. Thus, it is possible to achieve the semiconductor integrated circuit having not only the tolerance to the radiation ray but also the reduced circuit area.

In the above description, the circuit has a loop to facilitate understanding of the present invention. However, the configuration cannot be limited in the present invention.

In the present invention, it is possible to prevent the circuit from malfunctioning due to the irradiation of the radiation rays more certainly.

Also, in the present invention, it is possible to configure the circuit having high tolerance to the irradiation of the radiation rays with high operation speed.

1. A latch circuit comprising:
a first circuit configured to generate a first output signal from a first input signal and to generate a second output signal from a second input signal; and
a first logic circuit connected with said first circuit, and configured to generate a first logic output signal in response to said first output signal and to generate a second logic output signal in response to said second output signal,
wherein a first threshold of said first circuit when said first output signal is generated from said first input signal and a second threshold of said first circuit when said second output signal is generated from said second input signal are different from each other.

2. The latch circuit according to claim 1, further comprising:
a second circuit connected with said first logic circuit and configured to generate a third output signal from said first logic output signal and to generate a fourth output signal from said second logic output signal; and
a second logic circuit connected with said second circuit, and configured to output a third logic output signal to said first circuit as said first input signal in response to said third output signal, and to output a fourth logic output signal to said first circuit as said second input signal in response to said fourth output signal,
wherein a third threshold of said second circuit when said third output signal is generated from said first logic output signal and a fourth threshold of said second circuit when said fourth output signal is generated from said second logic output signal are different from each other.

3. The latch circuit according to claim 1, further comprising:
a second logic circuit connected with said first logic circuit, and configured to output a third logic output signal to said first circuit as said first input signal in response to said first logic output signal, and to output a fourth logic output signal to said first circuit as said second input signal in response to said second logic output signal.

4. The latch circuit according to claim 2, wherein at least one of said first circuit and said second circuit comprises:
a buffer circuit;
a first resistance component connected with an input of said buffer circuit in series; and
a second resistance component connected in parallel to said buffer circuit.

5. The latch circuit according to claim 4, wherein said buffer circuit comprises:
An first inverter; and
a second inverter connected with said first inverter in series, and
at least one of said first inverter and said second inverter is an NMOS inverter.

6. The latch circuit according to claim 5, wherein at least one of said first inverter and said second inverter comprises a PMOS inverter.

7. The latch circuit according to claim 4, wherein at least one of said first resistance component and said second resistance component comprises a silicon film resistance.

8. The latch circuit according to claim 4, wherein at least one of said first resistance component and said second resistance component comprises a MOS transistor.

9. The latch circuit according to claim 2, where each of said first logic circuit and said second logic circuit comprises an inverter.

10. The latch circuit according to claim 2, wherein each of said first logic circuit and said second logic circuit comprises a NOR circuit.

11. The latch circuit according to claim 2, wherein each of said first logic circuit and said second logic circuit comprises a NAND circuit.

12. A flip-flop circuit comprises:
a first circuit; and
a second circuit connected with said first circuit,
wherein said first latch circuit generates a first output signal based on a first threshold in response to a first input signal, and generates a second output signal based on a second threshold value different from said first threshold in response to a second input signal, and
said second circuit generates a third output signal from said first output signal to output to said first circuit as said first input signal, and generates a fourth output signal from said second output signal to output to said first circuit as said second input signal.

13. The flip-flop circuit according to claim 12, wherein said first circuit comprises a hysteresis circuit and a first specific circuit connected to said hysteresis circuit and said second circuit,
said hysteresis circuit generates a first inversion signal based on said first threshold in response to said first input signal, and generates a second inversion signal based on said second threshold value in response to said second input signal, and
said first specific circuit generates said first output signal from said first inversion signal and generates said second output signal from said second inversion signal.

14. The flip-flop circuit according to claim 13, wherein said first input signal is a signal transiting from a low level to a high level, and said second input signal is a signal transiting from the high level to the low level, and
said first threshold is higher than said second threshold.

15. A semiconductor memory circuit comprising:
a plurality of memory cell circuits arranged in a matrix,
wherein each of said plurality of memory cell circuits comprises:
a first circuit; and
a second circuit connected with said first circuit,
said first latch circuit generates a first output signal based on a first threshold in response to a first input signal, and generates a second output signal based on a second threshold value different from said first threshold in response to a second input signal, and
said second circuit generates a third output signal from said first output signal to output to said first circuit as said first input signal, and generates a fourth output signal from said second output signal to output to said first circuit as said second input signal.

16. The semiconductor memory circuit according to claim 15, wherein said first circuit comprises a hysteresis circuit and a first specific circuit connected to said hysteresis circuit and said second circuit,
said hysteresis circuit generates a first inversion signal based on said first threshold in response to said first input signal, and generates a second inversion signal based on said second threshold value in response to said second input signal, and said first specific circuit generates said first output signal from said first inversion signal and generates said second output signal from said second inversion signal.

17. The semiconductor memory circuit according to claim 16, wherein said first input signal is a signal transiting from a low level to a high level, and said second input signal is a signal transiting from the high level to the low level, and
said first threshold is higher than said second threshold.

18. The semiconductor memory circuit according to claim 16, further comprising:
a bit line connected with each of columns of said plurality of memory cell circuits; and
a word line connected with each of rows of said plurality of memory cell circuits.
